(19) United States
(12) Patent Application Publication
(10) Pub. No.: US 2010/0063758 A1
(43) Pub. Date: Mar. 11, 2010

(54) ELECTRONIC APPARATUS WITH POWER INDICATION FUNCTION

(76) Inventors: Ching-Hao Yu, Taipei (TW); Meng-Hsuan Shih, Taipei (TW); Wei-Chun Chien, Taipei (TW); Chien-Hsu Hou, Taipei (TW); Martijn Baller, Taipei (TW); Jia-Rong Lin, Taipei (TW); Chia-Ying Lee, Taipei (TW); Yen-Liang Chen, Taipei (TW); Yung-Chie Huang, Taipei (TW); Chi-Chen Lin, Taipei (TW)

Correspondence Address: Muncy, Geissler, Olds & Lowe, PLLC, P.O. BOX 1364, FAIRFAX, VA, 22038-1364, US

(21) Appl. No.: 12/554,688

(22) Filed: Sep. 4, 2009

(30) Foreign Application Priority Data
Sep. 5, 2008 (TW) 097134312

(51) Int. Cl. G01R 31/36; G01N 27/416; H01J 1/62

(52) U.S. Cl. 702/63; 324/427; 313/504

(57) ABSTRACT

An electronic apparatus with a power indication function is connected to an adapter. The electronic apparatus includes a host, a power jack, a rechargeable battery, a power indication element and a controller. The power jack is disposed on the host for connecting with the adapter. The rechargeable battery is disposed in the host and is electrically connected to the power jack. The power indication element has a switch disposed adjacent to the power jack and a power indicator disposed in the host. The controller is electrically connected to the rechargeable battery, the switch and the power indicator. When the switch turns on, the controller detects the remained power in the rechargeable battery and the remained power is indicated by the power indicator.

### CROSS REFERENCE TO RELATED APPLICATIONS

This Non-provisional application claims priority under 35 U.S.C. §119(a) on Patent Application No(s). 097134312 filed in Taiwan, Republic of China on Sep. 5, 2008, the entire contents of which are hereby incorporated by reference.

### BACKGROUND OF THE INVENTION

1. Field of Invention

The invention relates to an electronic apparatus and, in particular, to an electronic apparatus with a power indication function.

2. Related Art

In general, the power supply of an electronic apparatus is provided either by an external power source through the power cord, or from a rechargeable battery assembled in the electronic apparatus. When the remained power in the rechargeable battery is insufficient to drive the electronic apparatus, the charging of the rechargeable battery is needed. Generally, it is necessary to boot the electronic apparatus to realize the remained power in the rechargeable battery. This is very inconvenient when the user wants to know the remained power in the rechargeable battery and the electronic apparatus is powered off.

### SUMMARY OF THE INVENTION

Accordingly, an electronic apparatus which can indicate the remained power in the rechargeable battery is disclosed, even the electronic apparatus is powered off.

The invention provides an electronic apparatus with the power indication function including a host, a power jack, a rechargeable battery, a power indication element and a controller. The power jack is disposed on the host for connecting with the adapter. The rechargeable battery is disposed in the host and is electrically connected to the power jack. The power indication element has a switch disposed adjacent to the power jack and a power indicator disposed in the host. The controller is electrically connected to the rechargeable battery, the switch and the power indicator. No matter the host is powered on or off, the controller can detect the remained power in the rechargeable battery, and the remained power is indicated by the power indicator when the switch, which is electrically connected to the rechargeable battery, turns on.

In one embodiment of the invention, the switch is disposed around the power jack and is a press-controlled or touch-controlled switch.

In one embodiment of the invention, the power indicator is disposed in an opening of the host and adjacent to the switch, and is at least partially exposed out of the host.

In one embodiment of the invention, the host has a light-permeable region, and the power indicator is disposed corresponding to the light-permeable region.

In one embodiment of the invention, the power indication element further includes an optical unit. If the host has a light-permeable region, the power indicator is disposed corresponding to the light-permeable region, and the optical unit is disposed between the host and the power indicator. If the switch is at least partially light permeable, the optical unit is disposed between the switch and the power indicator. Herein, the optical unit is a light-guide unit, a diffuser, a color conversion unit or their combinations.

In one embodiment of the invention, the power indicator includes a sounding unit and/or a lighting unit. Herein, the lighting unit is a light-emitting diode (LED) or an organic light-emitting diode (OLED) for displays at least one color light.

In one embodiment of the invention, the controller is a digital signal processor (DSP), a central processing controller (CPU) or a micro-controller unit (MCU).

In one embodiment of the invention, the electronic apparatus with the power indication function is a portable electronic apparatus such as, for example but not limited to, a notebook computer, a hand-held PC, a PDA, an e-Book, a mobile communication device or a game console.

As mentioned above, the invention configures a power indication element, which includes the switch and the power indicator, so that the user can realize the remained power in the rechargeable battery without booting the host.

These and other features, aspects, and advantages of the invention will become better understood with regard to the following description, appended claims, and accompanying drawings.

### BRIEF DESCRIPTION OF THE DRAWINGS

FIG. 1 is a schematic diagram showing an electronic apparatus with a power indication function according to a preferred embodiment of the invention;

FIG. 2 is a block diagram of the electronic apparatus with a power indication function according to a preferred embodiment of the invention;

FIG. 3 is a schematic diagram showing a part of the electronic apparatus of FIG. 1;

FIG. 4 is a schematic diagram showing an electronic apparatus with a power indication function according to another preferred embodiment of the invention; and

FIG. 5 is a schematic diagram showing an electronic apparatus with a power indication function according to yet another preferred embodiment of the invention.

### DETAILED DESCRIPTION OF THE INVENTION

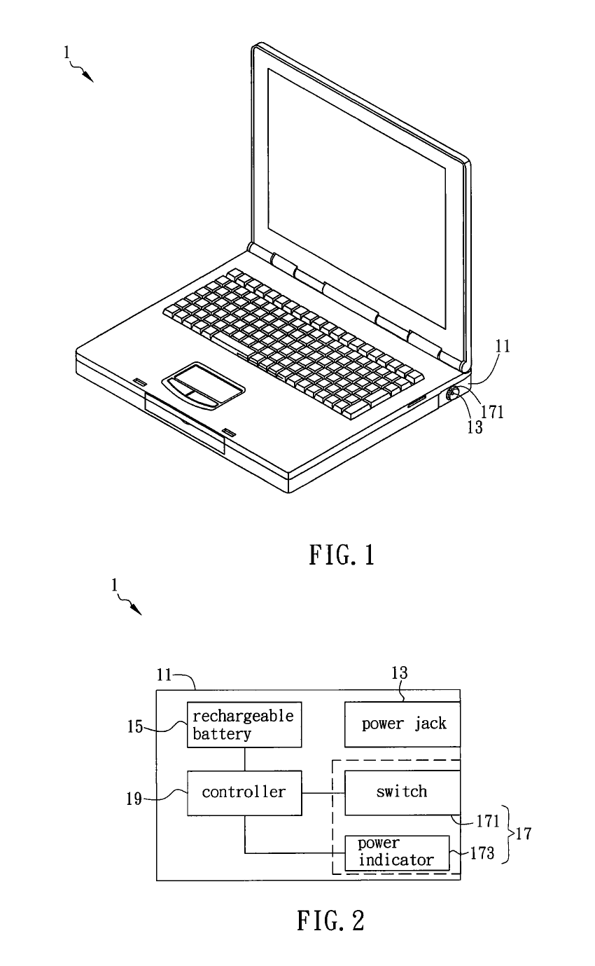

FIG. 1 is a schematic diagram showing an electronic apparatus with a power indication function according to a preferred embodiment of the invention, and FIG. 2 is a block diagram of the electronic apparatus with a power indication function according to a preferred embodiment of the invention. With reference to FIG. 1 and FIG. 2, this embodiment only takes a notebook computer for example, and the electronic apparatus of the invention can be, for example but not limited to, a notebook computer, a hand-held PC, a PDA, an e-Book, a mobile communication device or a game console.

The electronic apparatus I of the embodiment includes a host 11, a power jack 13, a rechargeable battery 15, a power indication element 17 and a controller 19. The power indication element 17 includes a switch 171 and a power indicator 173. The switch 171 can enable the function of detecting the remained power in the rechargeable battery 15, and then the controller 19 drives the power indicator 173 to operate in one of multiple indication modes according to the remained power in the rechargeable battery 15. Thus, it is possible to realize the remained power in the rechargeable battery 15 according to the power indicator 173 without booting the electronic apparatus 1.

The power jack 13 is disposed on the host 11, and the rechargeable battery 15 is disposed in the host 11 and electrically connected to the power jack 13. The controller 19 is electrically connected to the rechargeable battery 15, switch 171 and power indicator 173. In this embodiment, the controller 19 can be, for example but not limited to, a digital signal processor (DSP), a central processing controller (CPU) or a micro-controller unit (MCU).

The power indicator 173 is disposed on the host 11 and located adjacent to the switch 171, and the power jack 13 is located adjacent to the switch 171. When the switch 171 turns on, the controller 19 detects the remained power in the rechargeable battery 15, so that the remained power in the rechargeable battery 15 is indicated by the power indicator 173.

In this embodiment, the switch 171 is disposed around the power jack 13 for example. In more details, the switch 171 may be continuously or discontinuously disposed around the power jack 13. Hereinafter, the switch 171 is, for example but not limited to, a press-controlled switch. Of course, the switch 171 of the invention may be other kind of press-controlled switch or touch-controlled switch, such as a touch pad.

The power indicator 173 includes at least one lighting unit (not shown), which displays at least one color light. For example, the lighting unit can be a light-emitting diode (LED) or an organic light-emitting diode (OLED). If the power indicator 173 includes a plurality of lighting units, it may display different colors for indicating various levels of the remained power. Alternatively, the number of the lighted lighting units may increase as much as the remained power in the rechargeable battery 15; otherwise, it may decrease as less as the remained power in the rechargeable battery 15 (which means the rechargeable battery 15 needs to be charged).

Of course, the power indicator 173 may include a single lighting unit. If the lighting unit is monochromatic, the illumination of the lighting unit, which is controlled by the driving voltage, can indicate the remained power in the rechargeable battery 15. For example, brighter illumination of the lighting unit represents more remained power in the rechargeable battery 15. To be noted, the above-mentioned example is only one of various aspects of the invention, and the invention is not limited to this.

In addition, if the lighting unit cooperates with at least one optical unit (not shown), such as a color conversion unit, for changing the color of the light emitted from the lighting unit, the power indicator 173 may display multiple colors to indicate the various levels of the remained power.

The steps for detecting the remained power of the above-mentioned electronic apparatus 1 will be described hereinafter. In the following case, the power indicator 173 displays different colors to indicate the various levels of the remained power. Moreover, the power indication may be carried out by different patterns or flashing frequencies. Herein, the power indicator 173 only displays red, yellow and green to indicate the remained power in the rechargeable battery 15.

If the lighting unit emits green light according to the detecting result as the switch 171 is pressed, it means that the remained power in the rechargeable battery 15 is sufficient. If the lighting unit continuously emits yellow light, it means that the rechargeable battery 15 is going to be empty. If the lighting unit continuously emits red light, it means that the remained power in the rechargeable battery 15 is insufficient. In addition, the lighting unit can be turned off after pressing the switch 171 again; otherwise, the lighting unit may be turned on for a while and then be turned off automatically. If the switch 171 is pressed and the lighting unit only flashes several times, it means that the rechargeable battery 15 is needed to be charged.

The user may connect an adapter, such as a battery charger, to the electronic apparatus 1 by plugging the adapter to the power jack 13. The adapter can be further coupled to an external power source (AC power source), so that the rechargeable battery 15 can be charged.

To be noted, the above-mentioned example utilizing the optical changes of the power indicator 173 to indicate the remained power in the rechargeable battery 15 is used for illustration only instead of limiting the invention. Alternatively, the power indicator 173 may include a sounding unit (not shown) to indicate the remained power in the rechargeable battery 15. In this case, the user may select the voice reminding mode to realize the remained power in the rechargeable battery 15. For example, when the switch 171 is pressed and the sounding unit alerts according to the detecting result, it means that the rechargeable battery 15 is going to be low battery, so that some functions of the electronic apparatus I may not work. At this time, the user may decide whether to charge the rechargeable battery 15 or not based on the alert of the sounding unit, such as a voice message.

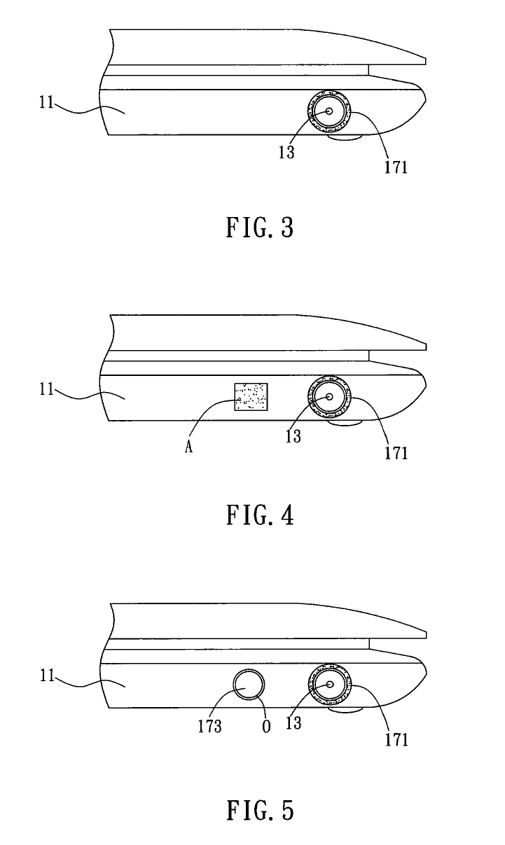

FIG. 3 is a schematic diagram showing a part of the electronic apparatus of FIG. 1. Referring to FIGS. 2 and 3, the power indicator 173 of the embodiment is disposed in the host 11. In order to uniformly guide the light emitted from the power indicator 173 to the switch 171, the power indication element 17 further includes an optical unit (not shown) disposed inside the host 11, and the switch 171 is partially light permeable. In more details, the optical unit of this embodiment can be a light-guide unit and/or a diffuser, which can be disposed between the light-permeable switch 171 and the power indicator 173, for uniforming the light emitted from the power indicator 173. To be noted that the above-mentioned aspect is used for illustration only instead of limiting the invention.

In addition, the switch 171, which is at least partially light permeable, can be divided into several regions (not shown). When the switch 171 is pressed, the power indicator 173 disposed in the host 11 can emit light to the switch 171 through the optical unit according to the detecting result. Then, one or more regions of the light-permeable switch 171 display the light. In this case, more regions that are capable of displaying the light represent that the rechargeable battery 15 contains more power.

FIG. 4 is a schematic diagram showing an electronic apparatus with a power indication function according to another preferred embodiment of the invention. With reference to FIGS. 2 and 4, the electronic apparatus of this embodiment is different from the previous one in that the power indicator 173 is disposed adjacent to the switch 171, and the host 11 has a light-permeable region A. In this embodiment, the optical unit (not shown) is disposed between the host 11 and the power indicator 173, so that the light emitted from the power indicator 173 can be uniformly projected onto the light-permeable region A of the host 11.

When the switch 171 is pressed, the power indicator 173 disposed in the host 11 can emit light to the light-permeable region A of the host 11 through the optical unit according to the detecting result. Accordingly, the user can realize whether the remained power in the rechargeable battery 15 is sufficient or not by reading the light-permeable region A. In this case, the light-permeable region A may show a simple symbol or pattern (not shown), so that the user can read the remained power as the light is projected onto the light-permeable region A.

Alternatively, several symbols or patterns, which can indicate the levels of the remained power, can be printed on the edge of the light-permeable region A of the host 11. Therefore, the user can determine the remained power in the rechargeable battery 15 according to the printed symbols or patterns around the light-permeable region A.

FIG. 5 is a schematic diagram showing an electronic apparatus with a power indication function according to yet another preferred embodiment of the invention. Referring to FIGS. 2 and 5, the electronic apparatus of the present embodiment is different from the previous one in that the power indicator 173 is partially exposed out of the host 11 and is disposed in an opening O of the host 11. In this embodiment, the power indicator 173 can directly emit the light out of the host 11 without the disposition of the optical unit.

When the switch 171 is pressed, the power indicator 173 exposed out of the host 11 can emit the light, so that the user can realize whether the remained power in the rechargeable battery 15 is sufficient or not by reading the emitted light.

In summary, the invention configures a power indication element, which includes the switch and the power indicator, so that the user can realize the remained power in the rechargeable battery without booting the host.

Although the invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic apparatus with a power indication function, which is connected to an adapter, comprising:
a host;
a power jack disposed on the host for connecting with the adapter;
a rechargeable battery disposed in the host and electrically connected to the power jack;
a power indication element having a switch disposed adjacent to the power jack and a power indicator disposed in the host; and
a controller electrically connected to the rechargeable battery, the switch and the power indicator,
wherein when the switch turns on, no matter the host is powered on or off, the controller detects a remained power in the rechargeable battery and the remained power is indicated by the power indicator.

2. The electronic apparatus according to claim 1, wherein the switch is disposed around the power jack.

3. The electronic apparatus according to claim 1, wherein the power indicator is at least partially exposed out of the host.

4. The electronic apparatus according to claim 1, wherein the power indicator is disposed adjacent to the switch.

5. The electronic apparatus according to claim 1, wherein the power indicator is disposed in an opening of the host.

6. The electronic apparatus according to claim 1, wherein the host has a light-permeable region, and the power indicator is disposed corresponding to the light-permeable region.

7. The electronic apparatus according to claim 1, wherein the power indication element further comprises:
an optical unit disposed between the host and the power indicator.

8. The electronic apparatus according to claim 7, wherein the optical unit is a light-guide unit, a diffuser, a color conversion unit or their combinations.

9. The electronic apparatus according to claim 1, wherein the switch is at least partially light permeable.

10. The electronic apparatus according to claim 9, wherein the power indication element further comprises:
an optical unit disposed between the switch and the power indicator.

11. The electronic apparatus according to claim 1, wherein the power indicator comprises a sounding unit or a lighting unit.

12. The electronic apparatus according to claim 11, wherein the lighting unit displays a color light.

13. The electronic apparatus according to claim 11, wherein the lighting unit is a light-emitting diode (LED) or an organic light-emitting diode (OLED).

14. The electronic apparatus according to claim 1, wherein the controller is a digital signal processor (DSP), a central processing controller (CPU) or a micro-controller unit (MCU).

15. The electronic apparatus according to claim 1, wherein the switch is a press-controlled switch or a touch-controlled switch.

16. The electronic apparatus according to claim 1, wherein the electronic apparatus is a portable electronic apparatus.

17. The electronic apparatus according to claim 16, wherein the portable electronic apparatus is a notebook computer, a hand-held PC, a PDA, an e-Book, a mobile communication device or a game console.
